(19) United States
(12) Patent Application Publication
(10) Pub. No.: US 2003/0117206 A1
(43) Pub. Date: Jun. 26, 2003

(54) High-frequency semiconductor device

(75) Inventor: Takahiro Ohnakado, Hyogo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/145,152

(22) Filed: May 15, 2002

(30) Foreign Application Priority Data
Dec. 26, 2001 (JP) 2001-394360

(51) Int. Cl. H03L 5/00

(52) U.S. Cl. 327/310

(57) ABSTRACT

An ESD (electrostatic discharge) protective circuit is connected to a node which is branching a high frequency signal input/output line connected to a high frequency input/output pad. A high frequency internal circuit is connected as a succeeding stage via a DC blocking capacitor such as a PIP (Polysilicon Insulator Polysilicon) capacitor, MIM (Metal Insulator Metal) capacitor, or comb capacitor to implement high ESD tolerability without significantly degrading high frequency characteristics.

### BACKGROUND OF THE INVENTION

1. Field of the Invention

The present invention relates to a high frequency semiconductor device, and more specifically, to a high frequency semiconductor device that provides a high frequency signal to an internal circuit from a high frequency signal line via a high frequency input/output pad.

2. Description of the Background Art

In recent years, as use of cellular phone spread and wireless LAN becomes practical, a high frequency semiconductor device has been attracting attention, which is essential to implement such electron devices with high performance and compactness, at low cost. As a material for implementing these high frequency semiconductor devices, III-V group compound semiconductors with high electron mobility, such as GaAs, have mainly been used. Meanwhile, Si-MOS transistor has rapidly been scaled down recently, and it is now possible to form MOS transistor with a very small gate length of less than 0.2 μm. As a result, transconductance Gm and high frequency characteristics thereof are highly improved to acquire characteristics applicable to gigahertz band/high frequency devices.

When an electrostatically charged object comes into contact with another object, a discharge phenomenon between these objects referred to as ESD (electrostatic discharge) occurs. ESD to a semiconductor device may cause a breakdown. The representative ESD models are; HBM (human body model) that models a discharge from a charged human body to a semiconductor device, MM (machine model) that models a discharge from a charged device to a semiconductor device, and CDM (charge device model) that models a discharge from a charged semiconductor device to a grounded object. Of these models, current waveform examples of HBM and CDM are shown in FIG. 20.

In FIG. 20, the ordinate indicates current value, whereas the abscissas indicates time. As should be apparent from FIG. 20, for HBM, stress of current up to about 1 A is produced during a relatively long time period of up to 10 μsec. For CDM, it can be appreciated that high stress of current up to 10 A is applied during a very short time period of up to 1 μsec.

As above, upon ESD, due to the high voltage applied to the semiconductor device in a short time period, a “thermal breakdown”, i.e., meltage by joule heat, is incurred. Additionally, when an MOS transistor structure, which is now utilized dominantly in LSI (large scaled integration) Si devices, is used, strong electric field of ESD applied to a gate oxide film thereof tends to result in breakdown. Accordingly, the breakdown caused by ESD is now highly concerned.

Therefore, various types of protective circuits are generally placed between an input/output pin (which is connected to a pad on a Si wafer via wire bonding, thus hereinafter will be described with reference to an input/output pad) and an internal circuit for preventing a surge of high voltage from flowing into the internal circuit upon ESD phenomenon, thus protecting the device from the breakdown. They are referred to as ESD protective circuits.

Currently, as an ESD protective circuit, a circuit described in “Novel Octagonal Device Structure for Output Transistors in Deep-Submicron Low-Voltage CMOS Technology” by M. D. Ker et. al., IEDM, pp. 889-892, 1996, is commonly used, in which an MOS transistor in an off state is connected to an input/output signal line.

FIG. 21 is a circuit diagram of a representative ESD protective circuit. As shown in FIG. 21, a P type MOS transistor TR1 has its gate, source, and N-well connected to external supply voltage VDD, with its drain connected to an input/output signal line. An N type MOS transistor TR2 has its gate, source and P-well grounded, with its drain connected to an input/output signal line connecting an input/output pad 1 and an internal circuit 2.

Since the two MOS transistors TR1 and TR2 are in an off state, they will not conduct current on normal operation and thus cause no effect on device operation.

On the other hand, when ESD surge flows into them from the input/output pad 1, a parasitic bipolar transistor operation, which will be described hereinafter, will occur, thereby forming paths through which high current flows from the drain to source.

FIG. 22 illustrates a parasitic bipolar transistor operation of an MOS transistor. Assume that a surge of positive voltage flows into the drain of N type MOS transistor TR2. First, positive voltage is applied to N⁺ diffusion layer 41 of the drain. As the voltage increases due to surge, reversely biased pn junction of N⁺ diffusion layer 41 suffers from breakdown, with large amount of electron-hole pairs being produced by an impact ionization phenomenon. Of those produced electron-hole pairs, the electrons are lead to the drain to which positive voltage is applied, while holes are lead to the grounded P-well 40. Thus, voltage drop occurs in the P-well 40 toward the depth direction, which can be expressed as I hole*R sub, where I hole is a magnitude of current produced by the holes lead to the P-well 40, and R sub is a value of resistance.

The voltage drop boosts potential of shallow portion of P-well area 40 under the gate of N type MOS transistor TR2 to a positive voltage. In the NPN parasitic bipolar transistor, which is configured with the drain N⁺ diffusion layer, shallow portion of P-well under the gate, and source N⁺ diffusion layer 42, the drain N⁺ diffusion layer and the shallow portion of P-well under the gate are reversely biased, while the shallow P-well portion under the gate 43 and source N⁺ diffusion layer 42 are positively biased. Thus, the parasitic NPN bipolar transistor turns on. When gate 43 is grounded and positive voltage surge of ESD is applied to the N type MOS transistor TR2 in an off state, the NPN parasitic bipolar turns on to allow high current flow.

Similar action takes place when a surge of negative voltage flows into the P type MOS transistor TR1. Further, when a surge of positive voltage flows into the drain of P type MOS transistor TR1, junction diode between the drain and N well is forwardly biased to turn on, causing a flow of current into N well. Similar action will occur when a surge of negative voltage flows into the drain of N type MOS transistor TR2.

Accordingly, by the ESD protective circuit using MOS transistor in an off state, high current can be lead to the ground line or internal supply voltage VDD line upon ESD, rather than lead to the internal circuit 2. Thus, as described above, the thermal breakdown and the breakdown of gate oxide film incurred by the high current flowing into the internal circuit 2 can be prevented.

It is well known that an MOS transistor in an off state must be carefully arranged in order to perform a good ESD protective function as described above. Specifically, as shown in FIG. 23, distance d, i.e., a distance between a gate electrode and a contact in the source or the drain diffusion layer of an MOS transistor, must be sufficiently long. According to the above mentioned article of M. D. Ker et. al., IEDM, pp. 889-892, 1996, the distance d should be at least 5 to 6 μm. The width of a source or the drain diffusion layer that is sandwiched between gate electrodes can be expressed as 2d+c, where c is the diameter of a contact. Therefore, it is apparent that when an MOS transistor is used as an ESD protective element that requires sufficiently long distance d, it is apparent that the width of the source or the drain diffusion layer becomes larger accordingly. Where design rule is 0.2 μm, c will be generally around 0.2 μm. Accordingly, width of a source or the drain diffusion layer 2d+c becomes larger, around 10.2 to 12.2 μm.

Therefore, to implement sufficient ESD protective function, for example, at least 100 μm of MOS transistor gate width is required. Further, a parasitic capacitance of source/drain diffusion layers (a capacitance of a depletion layer of a pn junction of source/drain diffusion layers and a well) per general unit area is 1 fF/μm² when the design rule is 0.2 μm. Thus, the parasitic capacitance between source/drain diffusion layers and Si substrate (well) of an MOS transistor used as an ESD protective element would be 1.02 to 1.22 pF, which is considerably large.

Such a large parasitic capacitance of an ESD protective element associated with Si substrate has not been a problem for a semiconductor memory or a logic device. It is, however, a serious concern for a high frequency device using a Si-MOS. A magnitude |z| of impedance z of capacitanor C can be expressed as 1/(2πfC), indicating that the magnitude |z| decreases as the frequency f increases. Further, the magnitude |z| further decreases as the capacitance C increases. Thus, when large drain diffusion layer capacitor is connected to the high frequency signal line, the magnitude of the impedance thereof at the high frequency will be very small.

As described in “High Q Inductors in a SiGe BiCMOS Process Utilizing a Thick Metal Process Add-on Module” by R. Groves et al., IEEE BCTM 9.3, pp. 149-152, 1999, a semi-insulating substrate with high resistance used in a compound semiconductor GaAs of high quality is difficult to obtain, thus a substrate with low resistance is used herein. Therefore, when an ESD protective element is connected to the high frequency signal line, the impedance of the large capacitor of the drain diffusion layer is very small at high frequency, and also resistance of the Si substrate to which the capacitor is connected is small, thus much of the high frequency signal on the high frequency line will be lead to the ESD protective element and eventually may be lost by the resistance of the Si substrate, as illustrated in FIG. 24, which shows a simple equivalent circuit of an ESD circuit using MOS transistor in an off state.

Thus, it is apparently difficult to implement a high frequency Si-MOS semiconductor device with high performance, reliability, and ESD tolerability by forming a ESD protective device.

### SUMMARY OF THE INVENTION

Therefore, the principle object of the present invention is to provide a semiconductor device of high performance and high reliability that realizes high tolerability against ESD without significantly degrading high frequency characteristics.

To summarize the present invention, one aspect of the present invention provides a high frequency semiconductor device with one end of a high frequency signal input/output line being connected to a high frequency input/output pad, including an internal circuit connected to the other end of a high frequency signal input/output line, a protective circuit connected between ground line and a node which is branching said high frequency signal input/output line connected to the high frequency input/output pad, and a DC blocking capacitor connected in series between the node and the internal circuit.

According to the present invention, the DC blocking capacitor corresponds to a first stage of an internal circuit so that the breakdown voltage increases significantly. Further, the effect of increased capacitance of the first stage of the internal circuit contributes to increase ESD surge tolerable current significantly. Therefore, ESD tolerability is improved and the current drivability of ESD protective circuit and the problematic parasitic capacitance associated therewith can significantly be reduced, thus degradation of high frequency characteristic can be prevented.

Another aspect of the present invention provides a high frequency semiconductor device with one end of a high frequency signal input/output line being connected to a high frequency input/output pad and having an MOS transistor, including an internal circuit connected to the other end of said high frequency signal input/output line and including a first stage circuit, and a protective circuit connected to a node branching the high frequency signal input/output line, wherein an insulation film thickness of the first stage circuit of said internal circuit is selected to be larger than an insulation film thickness of a gate insulation film of the MOS transistor.

Another aspect of the present invention provides a high frequency semiconductor device with one end of a high frequency signal input/output line being connected to a high frequency input/output pad and having an MOS transistor, including an internal circuit connected to the other end of the high frequency signal input/output line and having a first stage circuit, a protective circuit connected to a node branching the high frequency signal input/output line, wherein capacitance of the first stage circuit of the internal circuit is selected to be larger than that of a gate insulation film of the MOS transistor.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing an ESD protective circuit for use with a high frequency device in a first embodiment of the present invention.

FIG. 2 is a circuit diagram showing one example of an internal circuit of FIG. 1.

FIG. 3 is a block diagram showing a conventional ESD protective circuit.

FIG. 4 illustrates an ESD protective operation of a conventional high-density MOS transistor.

FIG. 5 illustrates an example of a capacitor formed with interlayer insulation films.

FIG. 6 is a table showing effects of the present invention and a conventional technique.

FIG. 7 is a circuit diagram of another variation of a first embodiment of the present invention.

FIG. 8 is a cross-sectional view of a PIP capacitor.

FIG. 9 is a circuit diagram of another variation of a first embodiment of the present invention.

FIG. 10 is a circuit diagram of another variation of a first embodiment of the present invention.

FIG. 11 is a circuit diagram of another variation of a first embodiment of the present invention.

FIG. 12 is a circuit diagram of another variation of a first embodiment of the present invention.

FIG. 13 is a circuit diagram of a second embodiment of the present invention.

FIG. 14 is a cross-sectional view of an MIM capacitor.

FIG. 15 is a circuit diagram of a variation of a second embodiment of the present invention.

FIG. 16 is a circuit diagram of another variation of a second embodiment of the present invention.

FIG. 17 is a circuit diagram of an example in which a DC blocking capacitor of a comb wiring is used as a third embodiment of the present invention.

FIG. 18 is a circuit diagram of a variation of a third embodiment of the present invention.

FIG. 19 is a circuit diagram of another variation of a third embodiment of the present invention.

FIG. 20 illustrates an example of electric current waveform of ESD.

FIG. 21 is a circuit diagram of a conventional ESD protective circuit using MOS transistor in an off state.

FIG. 22 illustrates operation of a parasitic bipolar transistor of ESD of an MOS transistor in an off state.

FIG. 23 shows a distance between the gate and a contact of an MOS transistor.

FIG. 24 shows a simple equivalent circuit of an ESD protective circuit using an MOS transistor in an off state.

### DESCRIPTION OF THE PREFERRED EMBODIMENTS

Referring to FIG. 1, a high frequency signal line has its one end connected to a high frequency input/output pad 1, with an ESD protective circuit 20 being connected thereto, and an internal circuit 2 of high frequency is connected as the succeeding circuit thereto via a DC blocking capacitor C3.

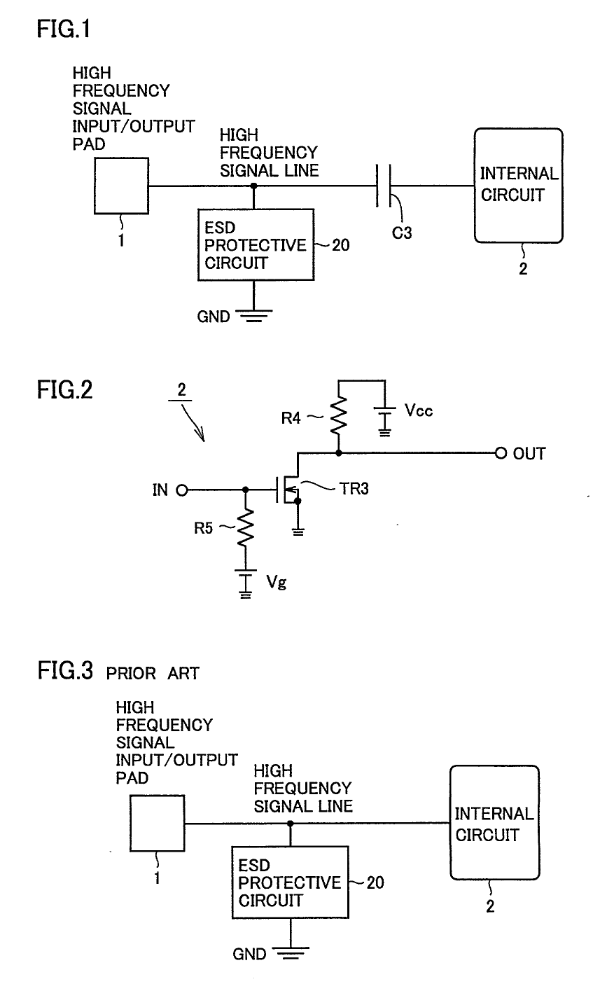

As shown in FIG. 2, the high frequency internal circuit 2 includes a low noise amplifier with its source grounded, for example. The amplifier includes an NMOS transistor TR3. To its gate, i.e., an input IN, gate voltage Vg is applied via a resistor R5. Its source is grounded, and its drain is provided with external power supply Vcc via a resistor to produce an output OUT.

In the input IN of such high frequency internal circuit 2, it is often required to remove direct current component, therefore a DC blocking capacitor C3 is connected to be the preceding stage of the internal circuit 2 for removing direct current component.

The DC blocking capacitor C3 needs to have a large capacitance value in order to have sufficiently low impedance at the operational frequency for passing a high frequency signal without any loss (for example, a capacitor of around 5 pF is employed, in case of 2 GHz operation). Forming such a large capacitor in a semiconductor chip requires a large area. Therefore, a DC blocking capacitor at an input unit for receiving an externally supplied signal is generally connected to a chip externally, rather than being formed thereon.

The present invention, however, is characterized in that the DC blocking capacitor, conventionally been attached externally, is placed on-chip as a succeeding stage to an ESD protective circuit. Further, by forming the DC blocking capacitor into a comb capacitor using a metal wiring, further improved characteristics can be realized.

In a conventional technique, as shown in FIG. 3, a high frequency signal line has one end connected to a high frequency input/output pad 1 and has its branch line connected to an ESD protective circuit 20 to protect high frequency internal circuit 2. In SIMOS process, an operation at high frequencies has been achieved by scaling down a device as described above. As a result, the gate oxide film of MOS transistor TR3 shown in FIG. 2 now has a extremely small thickness of 20 to 40 Å or less.

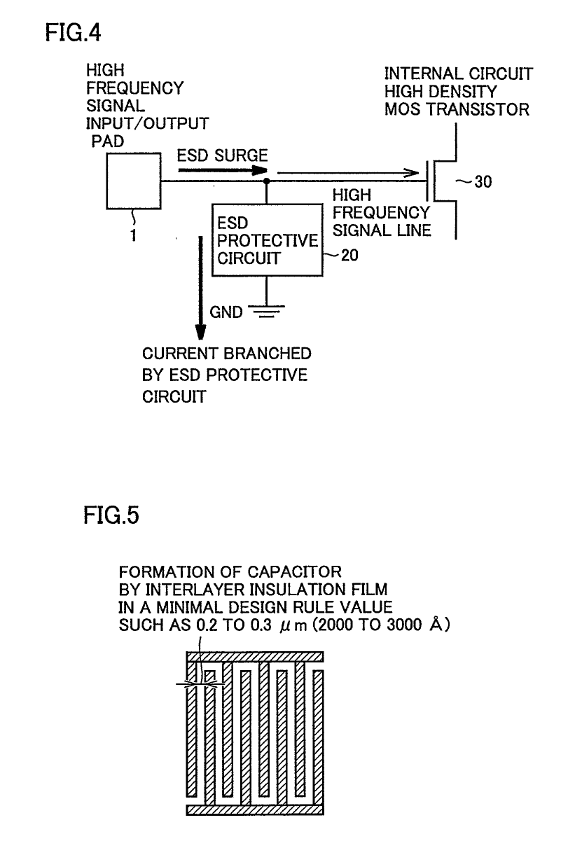

Considering a representative LNA (low noise amplifier) as a high frequency circuit, similar to the internal circuit to be protected from ESD shown in FIG. 4, a very thin firm of gate electrode is often placed as a preceding stage of the MOS transistor TR 3 shown in FIG. 2. In such a case, the thin oxide film can easily suffer breakdown by a surge of ESD. Unless the surge is fully branched by the ESD protective circuit to eliminate current leakage into the internal circuit 2, the ESD breakdown cannot be prevented. Thus, with the trend of gate oxide film becoming thinner as MOS transistor becoming smaller, it can be appreciated that the protection thereof from ESD is increasingly challenging than it had ever been.

Under such circumstances, when utilizing a DC blocking capacitor, as in the present invention, as a first stage circuit of an internal circuit to which ESD surge directly flows in, the thickness of the insulation film of the internal circuit that might suffers from breakdown is increased from the conventional thickness of 20 to 40 Å to a thickness of a insulation film forming a capacitor, usually 150 to 200 Å. It can be appreciated that the breakdown voltage will become higher by the increased amount of film thickness. Basically, the breakdown of an insulation film depends on the applied electric field. Thus, it is apparent that the breakdown voltage will become higher as the thickness of the insulation film increases. Here, consider the breakdown phenomenon of ESD.

First, part of ESD surge current that was not fully branched into the ESD protective circuit flows into the internal circuit 2, charging the capacitance of first stage of the internal circuit. Then the voltage of the first stage of the internal circuit boosts, exceeding the breakdown voltage of the insulation film. Thus, breakdown occurs. As above, by having the DC blocking capacitor of the present invention as the first stage of the internal circuit 2, not only the breakdown voltage can be made higher, but also additional effect described hereinafter will be attained.

In a conventional case where the gate of an MOS transistor is the first stage of the internal circuit 2, the capacitance of the first stage of the internal circuit has been at most 0.8 pF or less (the gate width of an MOS transistor used in LNA is generally 100 to 400 μm, of which capacitance is around 0.2 to 0.8 pF with the gate length of 0.2 μm). The DC blocking capacitor has a high value of 5 pF, as above, thus increasing the capacitance of the first stage of the internal circuit more than six times. Then,

Q=I*t=C*V, then I=C*V/t

where Q is charge, I is current, t is time, C is capacitance, and V is voltage.

As can be appreciated by above equation, if the capacitance is increased by a factor of six, then six times higher current is acceptable until the voltage is boosted to the same value. With this effect combined with the above mentioned effect of increasing breakdown voltage, one can understand that ESD surge tolerability is significantly improved.

Since there is no need to fully branch ESD surge current by the ESD protective circuit 20 any longer, it becomes allowable to reduce the capability of the ESD protective circuit 20 for driving current. Thus, when the ESD protective circuit 20 is configured with an MOS transistor in an off state, the gate width thereof can significantly be reduced. Accordingly, parasitic capacitance associated with formation of the ESD protective circuit 20 can significantly be reduced, thus the degradation of high frequency characteristics is prevented.

The DC blocking capacitor has conventionally been formed externally at an input terminal, which is for receiving an externally provided high frequency signal. There has been no advantage of forming it on-chip due to its limited area as described above and poor on-chip capacitor characteristics as compared to externally attached capacitor. According to one embodiment of the present invention, however, by forming a DC blocking capacitor deliberately on-chip to be a succeeding stage of an ESD protective circuit, unique effects are attained. Specifically, ESD tolerability of a high frequency device is improved, and the problem of significantly degraded high frequency characteristic due to the parasitic capacitance and parasitic resistance of an ESD protective circuit can be solved.

General on-chip capacitors are: a PIP capacitor (e.g., Polysilicon Insulator Polysilicon: K. Yamamoto et. al., IEEE J. Solid-State Circuits, Vol. 36, pp. 1186-1197, Aug. 2001) in which a silicon oxide film, a silicon nitride film, or a composite film thereof is sandwiched between two layers of polysilicon electrodes, or an MIM capacitor (Metal Insulator Metal, M. Armacost et. al., IEEE IEDM 2000) in which a silicon oxide film, a silicon nitride film, or a composite film thereof is sandwiched between two layers of metal electrodes in interlayer insulation films in metal wiring. Improvement of ESD tolerability can be attained by utilizing these capacitors as a DC blocking capacitor C3 formed as a succeeding stage of the ESD protective circuit 20 in an embodiment of the present invention, and also by utilizing comb capacitor formed by shaping metal wiring in a comb shape.

FIG. 5 is an example of forming a capacitor by interlayer insulation films. As shown, by forming metal wiring in a comb shape, a capacitor structured by the interlayer insulation films between metal wiring can be formed. In the most advanced silicon CMOS process, the design rule has been drastically reduced to have metal wiring width or intervals in several thousands Å. Therefore, a comb capacitor of high capacitance can now be formed with a practical layout area, making it possible to utilize such capacitor as a DC blocking capacitor C3 of the present invention.

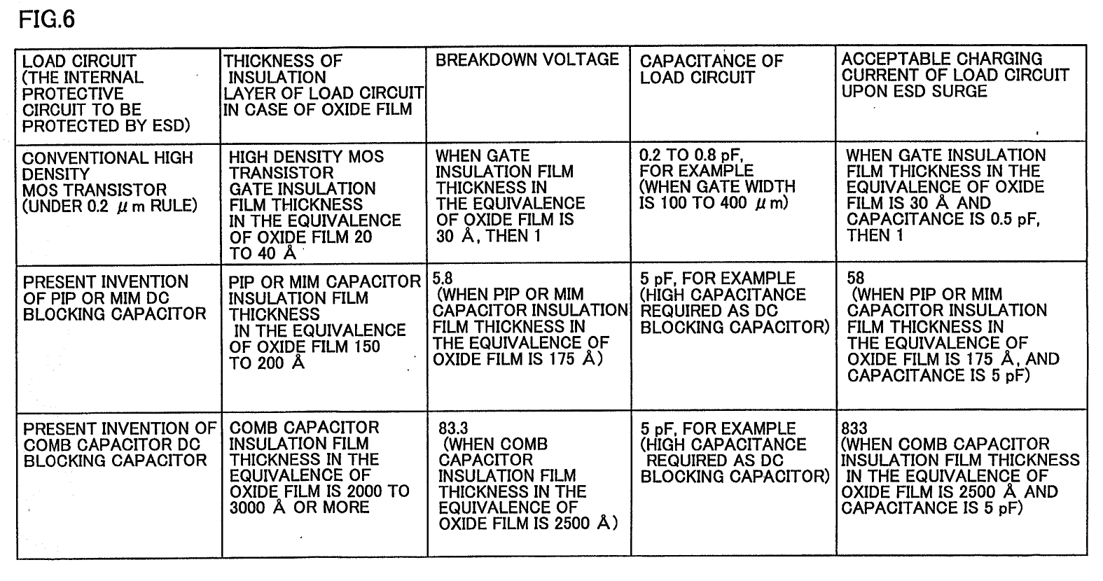

FIG. 6 shows a table of these effects. As can be seen, in case of PIP or MIM as above, the thickness of insulation film of 150 to 200 Å is increased to several thousands Å (around 2000 to 3000 Å in the most advanced process), indicating that the above-mentioned breakdown voltage is increased more than ten times.

As such, it is apparent that when a comb capacitor with basically the same configuration with usual metal wiring, i.e., having inherent ultra-high breakdown voltage thereof is arranged as the first stage of the internal circuit 2 which itself is the succeeding stage of a ESD protective circuit 20, the ESD tolerability can be increased significantly, and the current drivability and parasitic capacitance of the ESD protective circuit 20 can significantly be reduced.

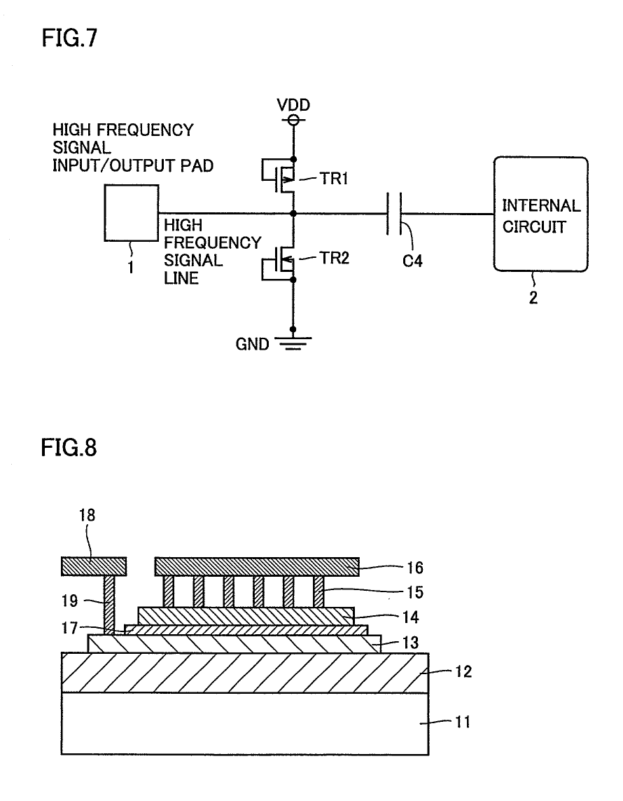

FIG. 7 is a circuit diagram of a variation of the first embodiment of the present invention. In FIG., 7, a high frequency signal line has its one end connected to a high frequency input/output pad 1. A branch line of the high frequency signal line is connected to an ESD protective circuit configured with a P type MOS transistor TR1 and an N type MOS transistor TR2. A high frequency internal circuit 2 as a succeeding stage is connected thereto, via a DC blocking capacitor C4 formed by a PIP capacitor, for example.

FIG. 8 is a sectional view of a PIP capacitor which is used as the DC blocking capacitor C4 of FIG., 7. As shown in FIG. 8, the PIP capacitor is structured as follows: an isolation oxide film 12 is formed on a silicon substrate 11, first and second polysilicon layers 13, 14 are formed thereon, and an insulation film 17 of a silicon oxide film, silicon nitride film, or a composite film thereof, are formed therebetween. A metal wiring 16 in the first layer is connected to the polysilicon 14 in the second layer via a contact 15, while a metal wiring 18 is connected to the polysilicon 13 in the first layer via a contact 19.

The insulation film thickness of a PIP capacitor corresponds, for example, to an oxide film of 150 to 200 Å. As an ESD protective element, an MOS transistor in an off state as shown in FIG. 7 can be utilized, with an N type MOS transistor TR2 connected to the ground line, and a P type MOS transistor TR1 connected to a VDD line.

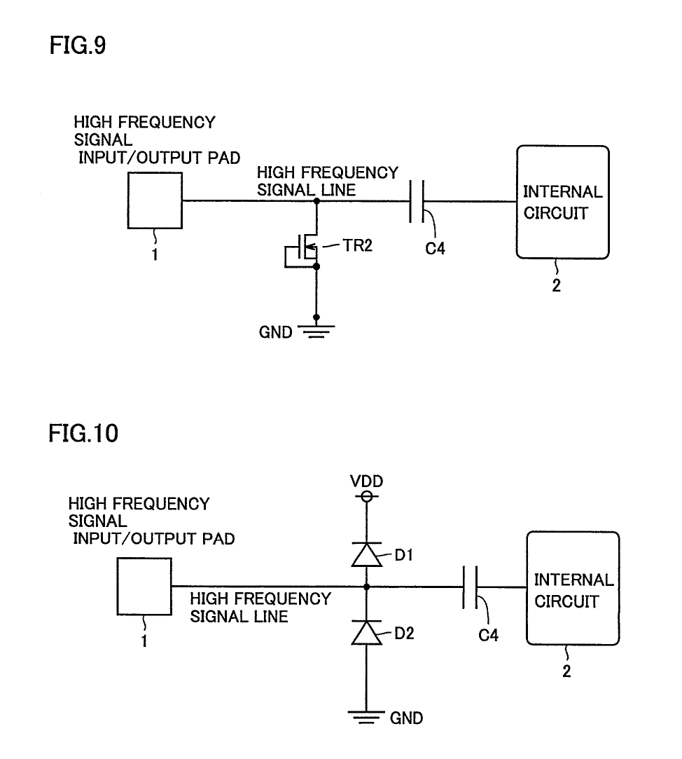

FIG. 9 is a circuit diagram of another variation of the first embodiment, in which only the N type MOS transistor TR2 connected to the ground line is utilized from the configuration shown in FIG. 7.

FIG. 10 is a circuit diagram of another variation of the first embodiment, with an ESD protective circuit configured with two diodes D1, D2 connected to the ground line and VDD line, respectively.

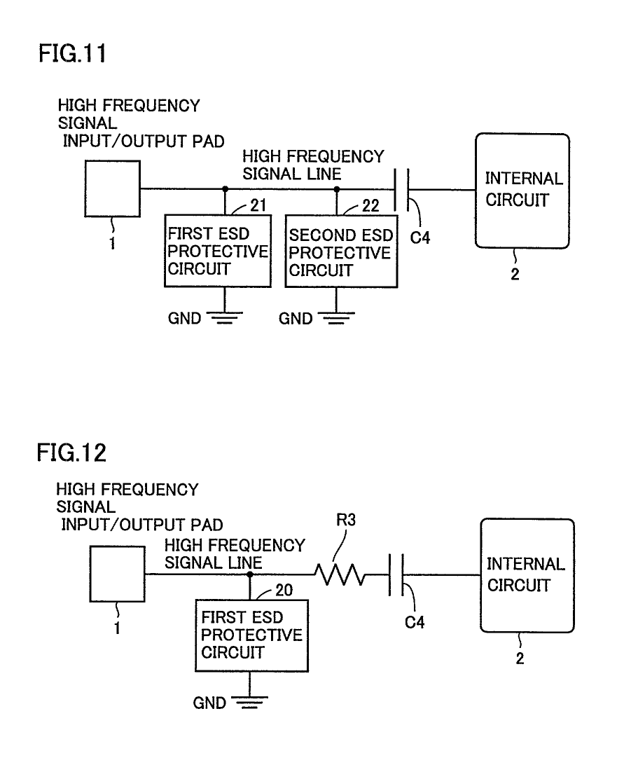

FIG. 11 is a circuit diagram of another variation of the first embodiment, in which a first ESD protective circuit 21 and a second ESD protective circuit 22 are connected in two stages between a high frequency signal line and ground line, with a DC blocking capacitor C4 being connected as a succeeding stage. These first and second ESD protective circuits 21 and 22 can be implemented with the N type MOS transistor TR2 as shown in FIG. 9.

FIG. 12 is a circuit diagram of another variation of the first embodiment. In this example, a resistor R3 for absorbing surge is connected between an ESD protective circuit 20 and a DC blocking capacitor C4.

As above, in the first embodiment of the present invention, DC blocking capacitor C4 formed with PIP capacitor corresponds to a first stage of the internal circuit 2, thus the breakdown voltage increases significantly. Further, the effect of increased capacitance of the first stage of the internal circuit contributes to increase ESD surge tolerable current significantly. Therefore, ESD tolerability is improved, and the current drivability of ESD protective circuit 20 and the problematic parasitic capacitance associated therewith can significantly be reduced, thus degradation of high frequency characteristic can be prevented. Thus, a high frequency semiconductor device with fairly high frequency characteristics and high reliability can be provided.

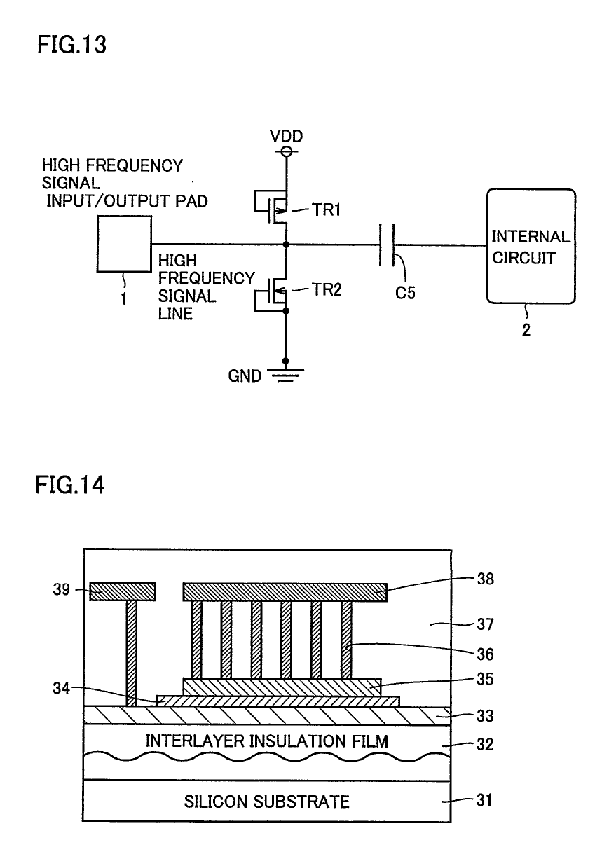

FIG. 13 is a circuit diagram of a second embodiment of the present invention. FIG. 14 is a cross-sectional view illustrating one example of the MIM capacitor shown in FIG. 13.

In FIG. 13, a high frequency signal line has its one end connected to a high frequency input/output pad 1, and has its branch line connected to an ESD protective circuit configured with a P type MOS transistor TR1 and an N type MOS transistor TR2. A DC blocking capacitor C5, configured of MIM capacitor and having a structure as shown FIG. 14, is connected thereto as a succeeding stage, thus forming a high frequency internal circuit.

The MIM capacitor shown in FIG., 14 is structured as follows: an interlayer insulation film 32 is formed on a silicon substrate 31, with metal wiring 33 as an underlayer formed thereon. On the metal wiring 33, an insulation film layer 34 that acts as a capacitor is formed. The insulation film layer 34 is made of a silicon oxide film, a silicon nitride film or a composite film thereof, and its thickness is around 150 to 200 Å in the equivalence oxide film, for example. On the insulation film layer 34, upper electrode layer 35 is formed, with interlayer insulation film 37 being formed thereon and connected to metal wiring 38 of the upper layer through via hole 36.

As an ESD protective element, an MOS transistor in an off state is used, for example, with an N type MOS transistor TR2 connected to the ground line and P type MOS transistor TR1 connected to VDD line.

FIG. 15 shows a variation of the second embodiment shown in FIG. 13, in which the N type MOS transistor TR2 connected to the ground line only is connected and the P type MOS transistor TR1 omitted.

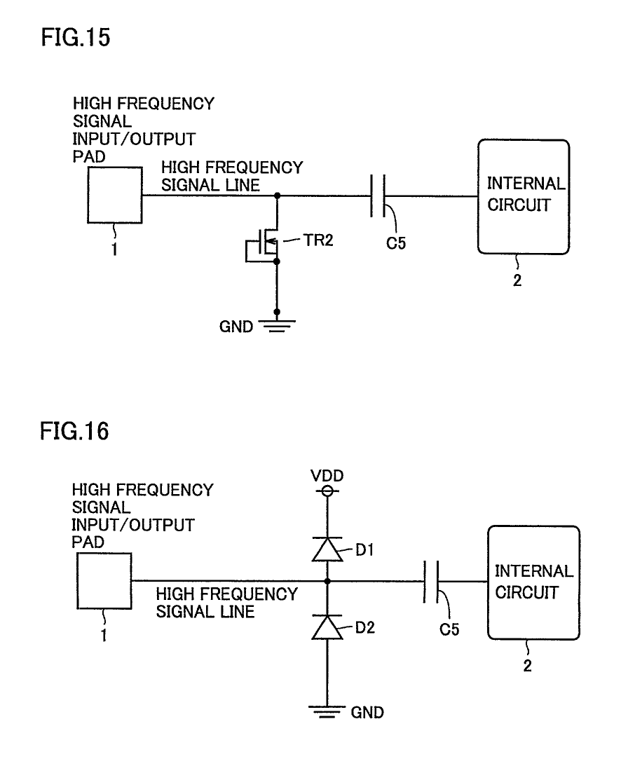

FIG. 16 shows another variation of the second embodiment, in which two diodes D1 and D2 are connected between VDD line and ground line to form an ESD protective circuit.

As above, in the second embodiment of the present invention, DC blocking capacitor C5 formed with MIM capacitor corresponds to a first stage of the internal circuit 2, and thus the breakdown voltage increases significantly. Further, the effect of increased capacitance of the first stage of the internal circuit contributes to increase ESD surge tolerable current significantly. Therefore, ESD tolerability is improved and the current drivability of ESD protective circuit 20 and the problematic parasitic capacitance associated therewith can significantly be reduced, thus degradation of high frequency characteristic can be prevented. Thus, a high frequency semiconductor device with fairly high frequency characteristics and high reliability can be provided.

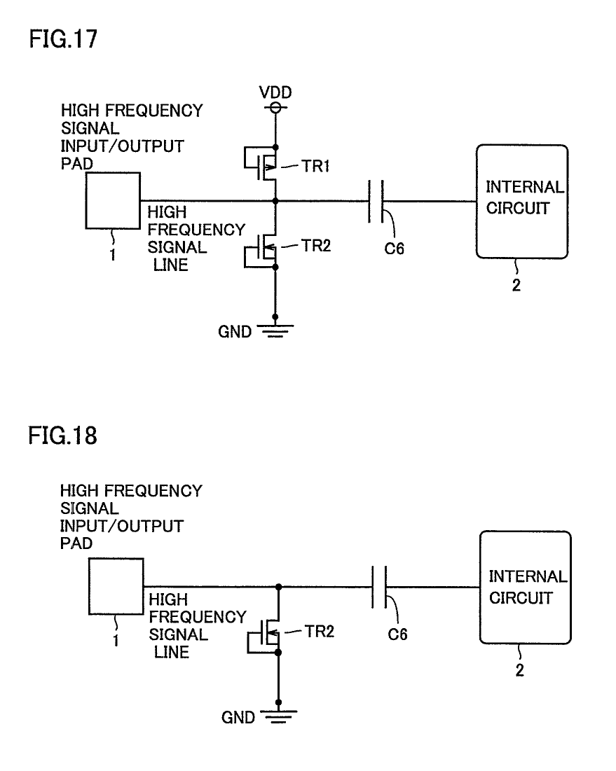

FIG. 17 is a circuit diagram illustrating a third embodiment of the present invention. In the present embodiment, an ESD protective circuit is connected via a branch line to a high frequency signal line which itself is connected to a high frequency input/output pad 1, with a high frequency internal circuit being connected as a succeeding stage via a DC block capacitor C6 of a comb capacitor having the structure shown in FIG. 4. By forming metal wire into a comb shape, an interlayer film between metal wiring can be utilized as an insulation film capacitance to form a capacitor.

In the most advanced silicon CMOS process, the design rule has been drastically reduced to have metal wiring width or intervals in several thousands Å (e.g., around 2000 to 3000 Å in the most advanced process). Therefore, a comb capacitor of high capacitance can now be formed with a practical layout area. As an ESD protective element, an MOS transistor in an off state is used, for example, with an N type MOS transistor TR2 connected to the ground line and P type MOS transistor TR1 connected to VDD line.

FIG. 18 shows a variation of the third embodiment shown in FIG. 17. In the present embodiment, the N type MOS transistor TR2 connected to the ground line is only utilized and the P type MOS transistor TR1 shown in FIG. 17 is omitted.

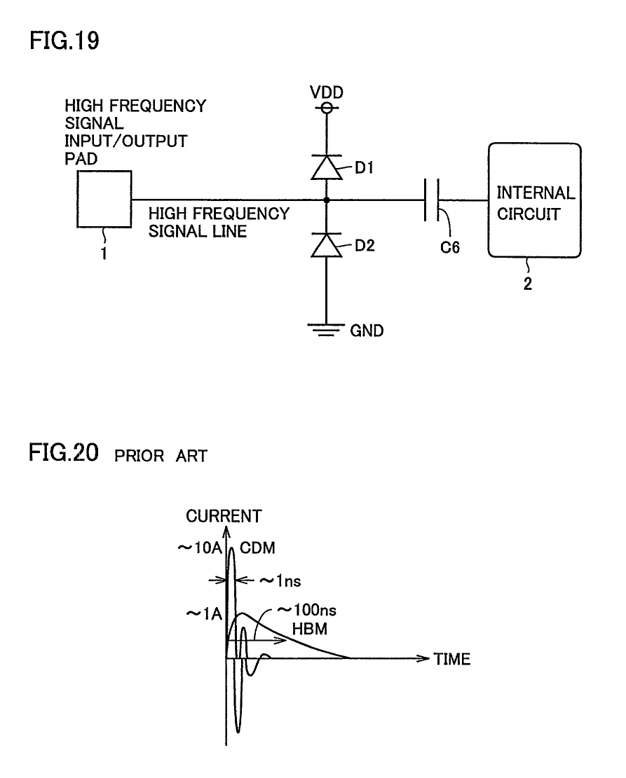

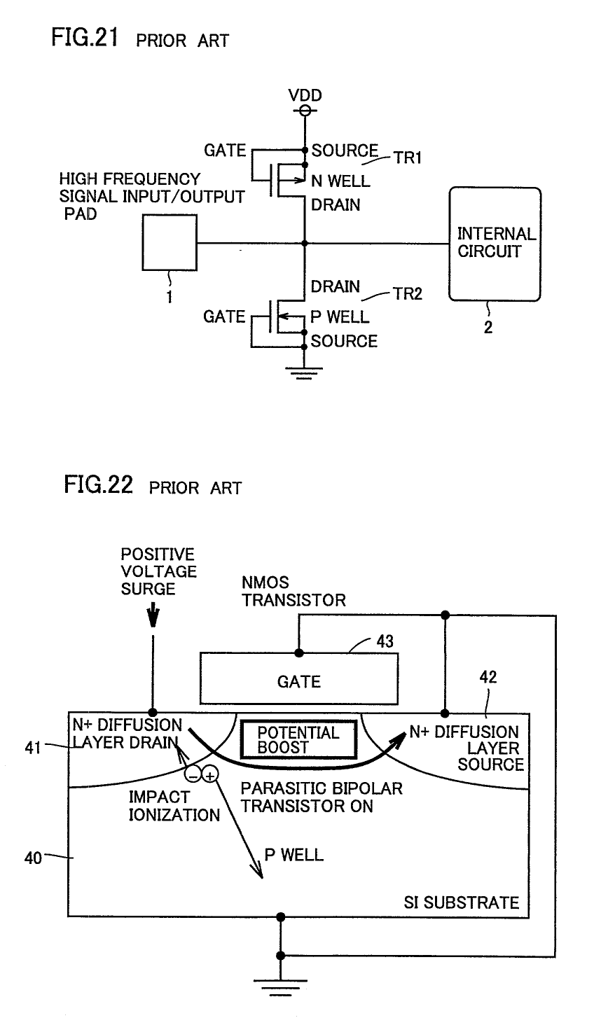

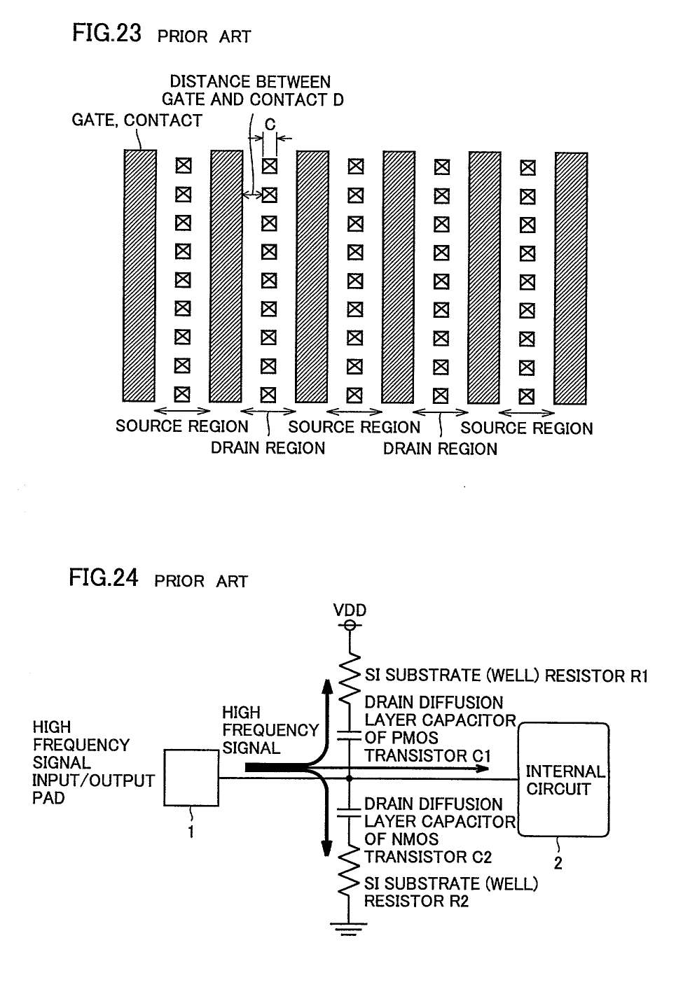

FIG. 19 illustrates another variation, and an ESD protective circuit is configured with two diodes D1 and D2 connected between ground line and VDD line.

As above, in the third embodiment of the present invention, DC blocking capacitor C6 formed with comb capacitor corresponds to a first stage of the internal circuit 2, thus the breakdown voltage increases significantly. Further, the effect of increased capacitance of the first stage of the internal circuit contributes to increase ESD surge tolerable current significantly. Therefore, ESD tolerability is improved and the current drivability of ESD protective circuit 20 and the problematic parasitic capacitance associated therewith can significantly be reduced, thus degradation of high frequency characteristic can be prevented. Thus, a high frequency semiconductor device with fairly high frequency characteristics and high reliability can be provided.

As above, in the conventional technique, the first circuit of the internal circuit is generally the gate of MOS transistor with very thin film gate oxide film, with low breakdown voltage and no tolerability against ESD, thus the current drivability of ESD circuit is required to be very high. In the present invention, however, DC blocking capacitor corresponds to first stage of an internal circuit, and thus the breakdown voltage increases significantly. Further, the effect of increased capacitance of the first stage of the internal circuit contributes to increase ESD surge tolerable current significantly. Therefore, ESD tolerability is improved and the current drivability of ESD protective circuit and the problematic parasitic capacitance associated therewith can significantly be reduced, and thus degradation of high frequency characteristic can be prevented. Thus, a high frequency semiconductor device with fairly high frequency characteristics and high reliability can be provided.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A high frequency semiconductor device having one end of a high frequency signal input/output line connected to a high frequency input/output pad, comprising:
an internal circuit connected to the other end of said high frequency signal input/output line;
a protective circuit connected between a node and a ground line, said node branching said high frequency signal input/output line connected to the high frequency input/output pad; and
a DC blocking capacitor connected in series between said node of the high frequency signal input/output line and said internal circuit.

2. The high frequency semiconductor device according to the claim 1, wherein
said DC blocking capacitor is formed by utilizing an insulation film capacitor between polysilicon electrodes.

3. The high frequency semiconductor device according to the claim 1, wherein
said DC blocking capacitor is formed by utilizing an insulation film capacitor between metal electrodes.

4. The high frequency semiconductor device according to the claim 1, wherein
said DC blocking capacitor is formed by utilizing a comb capacitor formed with a metal wiring.

5. The high frequency semiconductor device according to claim 1, wherein
said protective circuit comprising
a first protective circuit connected between a node and a ground line, said node branching said high frequency signal input/output line connected to the high frequency input/output pad; and
a second protective circuit connected between said node and the ground line.

6. The high frequency semiconductor device according to the claim 5, wherein
said DC blocking capacitor is formed by utilizing an insulation film capacitor between polysilicon electrodes.

7. The high frequency semiconductor device according to the claim 5, wherein
said DC blocking capacitor is formed by utilizing an insulation film capacitor between metal electrodes.

8. The high frequency semiconductor device according to the claim 5, wherein
said DC blocking capacitor is formed by utilizing a comb capacitor formed with a metal wiring.

9. A high frequency semiconductor device having one end of a high frequency signal input/output line connected to a high frequency input/output pad and having an MOS transistor, comprising:
an internal circuit connected to the other end of said high frequency signal input/output line and including a first stage circuit; and
a protective circuit connected to a node branching said high frequency signal input/output line; wherein
an insulation film thickness of the first stage circuit of said internal circuit is selected to be larger than an insulation film thickness of a gate insulation film of said MOS transistor.

10. A high frequency semiconductor device having one end of a high frequency signal input/output line connected to a high frequency input/output pad and having an MOS transistor, comprising:
an internal circuit connected to the other end of said high frequency signal input/output line and including a first stage circuit; and
a protective circuit connected to a node branching said high frequency signal input/output line; wherein
capacitance of the first stage circuit of said internal circuit is selected to be larger than an insulation film capacitance of a gate insulation film of said MOS transistor.
